(19) United States
(12) Patent Application Publication
(10) Pub. No.: US 2008/0205582 A1
(43) Pub. Date: Aug. 28, 2008

(54) PROCESSING ELEMENT AND RECONFIGURABLE CIRCUIT INCLUDING THE SAME

(75) Inventor: Hiroshi Furukawa, Kawasaki (JP)

Correspondence Address: STAAS & HALSEY LLP, SUITE 700, 1201 NEW YORK AVENUE, N.W., WASHINGTON, DC, 20005, US

(73) Assignee: Fujitsu Limited, Kawasaki (JP)

(21) Appl. No.: 12/033,969

(22) Filed: Feb. 20, 2008

(30) Foreign Application Priority Data
Feb. 22, 2007 (JP) 2007-42361

(51) Int. Cl. G11C 19/00

(52) U.S. Cl. 377/77

(57) ABSTRACT

A processing element includes a shift register including n stages of registers mutually connected in series. Data held among the n stages of registers is rotated in synchronization with a clock signal. A number-of-stages determining circuit determines the number of stages to be used among the n stages of registers. An output terminal of the register in the last stage connects to an input terminal of the register in the first stage.

### BACKGROUND

1. Field

The embodiments discussed herein are directed to a processing element capable of dynamically changing a circuit configuration and a reconfigurable circuit including the processing element.

2. Description of the Related Art

FIG. 1 illustrates a schematic configuration of a conventional reconfigurable LSI (large scale integration) 101 including a processing element (PE) having a predetermined function. The reconfigurable LSI 101 constitutes a product-sum circuit to perform a product-sum operation on input data and predetermined coefficients. As illustrated in FIG. 1, the reconfigurable LSI 101 includes a counter element 103 to count the number of inputs of input data DI, a RAM (random access memory) element 104 to store predetermined memory data DI1, a multiplier element 105 to multiply the input data DI by the memory data DI1, and an accumulating adder element 106 to cumulatively add pieces of multiplication data output from the multiplier element 105. Also, the reconfigurable LSI 101 includes a data delay element 107 to adjust the timing when the input data DI is input to the multiplier element 105. Furthermore, the reconfigurable LSI 101 includes an enable delay element 108 to adjust the timing when an enable signal ENB generated by the counter element 103 is input to the accumulating adder element 106.

The counter element 103 includes an adder 103a to add the number of inputs of the input data DI, a register 103b to temporarily hold addition data generated by the adder 103a, and an enable signal generator 103c to generate and output an enable signal ENB. For example, the enable signal generator 103c outputs an enable signal ENB, which is data of “1”, at predetermined intervals based on the addition data. The adder 103a adds “1” to the addition data held in the register 103b every time input data DI is input to the counter element 103. Thus, the input data DI corresponds to the addition data output from the adder 103a.

The RAM element 104 includes a storage unit 104a to store the memory data DI1. Addition data DOa output from the counter element 103 is input to a read-address input terminal RA of the storage unit 104a. The addition data DOa corresponds to the input data DI. Thus, by using the addition data DOa as a read-address signal of the storage unit 104a, the memory data DI1, which is to be multiplied by the input data DI, can be read.

Predetermined time is required from when the input data DI is input to the counter element 103 until when the memory data DI1 is output from the RAM element 104, due to processing time in the elements 103 and 104. For example, one clock cycle is required for the counter element 103 to count the number of inputs of the input data DI and output the addition data DOa. Also, one clock cycle is required for the RAM element 104 to read the memory data DI1 and output the addition data DOa. In this case, output timing of the memory data DI1 read from the RAM element 104 delays by two clock cycles with respect to input timing of the input data DI to the counter element 103. Thus, the input data DI is input to the multiplier element 105 via the data delay element 107 so that the input data ID and the memory data DI1 corresponding to the same addition data DOa are input to the multiplier element 105 almost simultaneously. The data delay element 107 includes a register group 107a to delay the input data DI. The register group 107a includes two registers connected to each other in series so as to delay the input data DI by two clock cycles, for example.

The multiplier element 105 includes a multiplier 105a to which the input data DI and the memory data DI1 are input and a register 105b to temporarily hold multiplication data generated by the multiplier 105a. The accumulating adder element 106 includes an adder 106a and a register 106b to temporarily store addition data generated by the adder 106a. The adder 106a adds the multiplication data output from the multiplier element 105 and the addition data held in the register 106b. Thus, the accumulating adder element 106 can cumulatively add pieces of multiplication data generated by the multiplier element 105.

If an enable signal ENB of data corresponding to “1” is input to the accumulating adder element 106, for example, the accumulating adder element 106 ends cumulative addition of data and outputs cumulative addition data as output data DO. Output timing of the memory data DI delays by one clock cycle with respect to input timing of the addition data DOa to the RAM element 104. Thus, the enable signal ENB is input to the accumulating adder element 106 via the enable delay element 108 so that the output data DO is output after the accumulating adder element 106 has accumulated a desired number of pieces of multiplication data. The enable delay element 108 includes a register 108a to delay the enable signal ENB by one clock cycle, for example.

At multiplication of the memory data DI1 by the input data DI, the reconfigurable LSI 101 allows the RAM element 104 to store the memory data DI1 and sequentially reads the memory data DI1 from the RAM element 104 by using addition data based on the number of data inputs counted by the counter element 103. When a product-sum operation is performed, the reconfigurable LSI 101 calculates the number of accumulations of data by using the counter element 103. Furthermore, the reconfigurable LSI 101 generates the enable signal ENB controlling the number of accumulations by using the counter element 103 and input the signal to the accumulating adder element 106.

When the reconfigurable LSI 101 performs a cumulative operation, the reconfigurable LSI 101 counts the number of accumulations by using the counter element 103 (the element other than the accumulating adder element 106 to accumulate data), output a control signal, and input the control signal to each operation element.

FIGS. 2 to 5 are for illustrating a conventional image processing reconfigurable LSI. FIG. 2 illustrates an image area 110 to be processed. As illustrated in FIG. 2, the image area 110 includes a plurality of pixels (not illustrated) arranged in a matrix pattern of m rows and n columns. As illustrated on the right side of FIG. 2, part of the plurality of pixels is used as an operation execution unit for image processing. In FIG. 2, adjoining nine pixels in three rows and three columns: x22, x23, x24, x32, x33, x34, x42, x43, and x44, are illustrated as an operation execution unit. Image processing is performed on the pixels x22, x23, x24, x32, x34, x42, x43, and x44 around the pixel x33, which is positioned at the center of the operation execution unit to serve as a target pixel.

FIG. 3 illustrates a spatial filter 111 used for image processing. The spatial filter 111 is used to read image data in units of pixels and rows, perform a predetermined operation on a target pixel and surrounding pixels, and replace a target pixel value. Various image processing results can be obtained by changing an operator. In this example, the operation execution unit of image processing includes three rows and three columns, and thus the spatial filter 111 also includes three rows and three columns. For example, if all of coefficients a00, a10, a20, a01, a11, a21, a02, a12, and a22 (hereinafter referred to as a00 to a22) of the spatial filter 111 are set to 1/9, the spatial filter 111 functions as an average filter. An average filter means a filter to extract an average of pixels around the target pixel. A filter process is performed by adding all values of image data of the pixels included in the operation execution unit, dividing the value obtained through the addition by 9 by using the average filter, and setting the value obtained through the division as a new pixel value of the target pixel. Accordingly, a blurred image can be obtained as a display image.

FIG. 4 illustrates three rows of image data segments x00 to x0n, x10 to x1n, and x20 to x2n stored in line buffers LB0 to LB2, respectively. FIG. 5 illustrates a reading state of the image data segments x00 to x0n, x10 to x1n, and x20 o x2n from the line buffers LB0, LB1, and LB2. As illustrated in FIG. 4, the image data segment x11 of the target pixel and the image data segments x00, 01, x02, x10, x12, x20, x21, and x22 of the pixels around the target pixel x11 are selected as an operation execution unit x1 and are read from the line buffers LB0, LB1, and LB2. The image data segments x00, 01, x02, x10, x11, x12, x20, x21, and x22 (hereinafter referred to as x00 to x22) read from the line buffers LB0, LB1, LB2 are input to a counter element and a data delay element. Input data DIO including the image data segments x00, x10, and x20, input data DI1 including the image data segments x01, x11, and x21, and input data DI2 including the image data segments x02, x12, and x22 are input in this order to the counter element and the data delay element.

As illustrated in FIG. 5, the image data segments x00 to x0n, x10 to x1n, and x20 to x2n are sequentially read from the line buffers LB0 to LB2 in the order of the operation execution unit x1, operation execution unit x2, and operation execution unit x3. Reading of the image data segments x01, x02, x11, x12, x21, and x22 included in the operation execution unit x2 from the line buffers LB0 to LB2 starts before all of the image data segments x00 to x22 included in the operation execution unit x1 have been read. Accordingly, the image processing reconfigurable can perform a pipeline process.

A filter process based on the spatial filter 111 is performed on the image data segments x00 to x22 and so on in the operation execution units x1, x2, and x3 read from the line buffers LB0 to LB2. If all of the coefficients a00 to a22 of the spatial filter 111 are set to 1/9, the image data segments x11, x12, and x13 of the target pixels of the operation execution units x1, x2, and x3 become new image data segments y11, y12, and y13, as expressed by the following expressions (1) to (3). Accordingly, a blurred image can be generated.

y11=(1/9)×x00+(1/9)×x01+(1/9)×x02+(1/9)×x10+(1/9)×x11+(1/9)×x12+(1/9)×x20+(1/9)×x21+(1/9)×x22 (1)

y12=(1/9)×x01+(1/9)×x02+(1/9)×x03+(1/9)×x11+(1/9)×x12+(1/9)×x13+(1/9)×x21+(1/9)×x22+(1/9)×x23 (2)

y13=(1/9)×x02+(1/9)×x03+(1/9)×x04+(1/9)×x12+(1/9)×x13+(1/9)×x14+(1/9)×x22+(1/9)×x23+(1/9)×x24 (3)

The image processing reconfigurable LSI requires the RAM elements to store the coefficients a00 to a22 of the spatial filter 111 and read the coefficients therefrom, the counter element to generate a read address signal, and the data delay element to adjust delay of the input data DI. Furthermore, a network is disadvantageously occupied to connect these elements.

### SUMMARY

It is an aspect of the embodiments discussed herein to provide a processing element including a shift register including n stages of registers mutually connected in series, and rotating held data among the n stages of registers in synchronization with a clock signal and a number-of-stages determining circuit determining the number of stages to be used among the n stages of registers, wherein an output terminal of the register in the last stage connects to an input terminal of the register in the first stage.

These together with other aspects and advantages which will be subsequently apparent, reside in the details of construction and operation as more fully hereinafter described and claimed, reference being had to the accompanying drawings forming a part hereof, wherein like numerals refer to like parts throughout.

The above-described embodiments of the present invention are intended as examples, and all embodiments of the present invention are not limited to including the features described above.

### BRIEF DESCRIPTION OF THE DRAWINGS

FIG. 1 illustrates a schematic configuration of a conventional reconfigurable LSI;

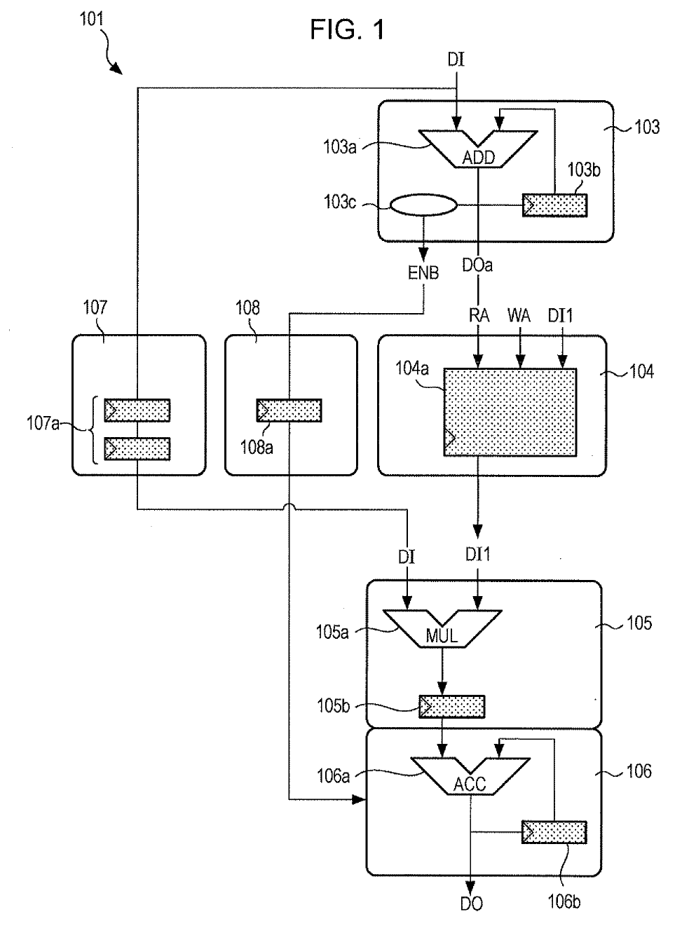

FIG. 2 illustrates a conventional image processing reconfigurable LSI, specifically illustrating an image area to be processed;

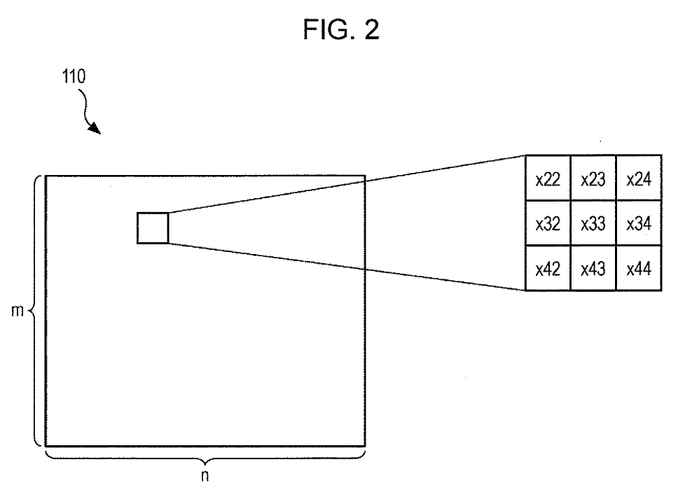

FIG. 3 illustrates the conventional image processing reconfigurable LSI, specifically illustrating a spatial filter 111 for image processing;

FIG. 4 illustrates the conventional image processing reconfigurable LSI, specifically illustrating image data segments of three lines stored in line buffers;

FIG. 5 illustrates the conventional image processing reconfigurable LSI, specifically illustrating a reading state of the image data segments from the line buffers;

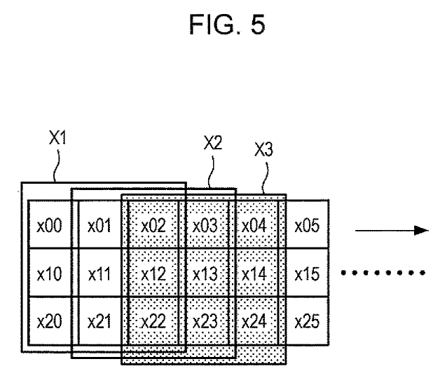

FIG. 6 illustrates a schematic configuration of an image processing reconfigurable LSI;

FIG. 7 illustrates a schematic configuration of a processing element according to example 1;

FIG. 8 illustrates a schematic configuration of a processing element according to example 2;

FIG. 9 illustrates a schematic configuration of a processing element according to example 3;

FIG. 10 illustrates a schematic configuration of a processing element according to example 4;

FIG. 11 illustrates a schematic configuration of a processing element according to example 5;

FIG. 12 illustrates a schematic configuration of a processing element according to example 6;

FIG. 13 illustrates a schematic configuration of a processing element according to example 7;

FIG. 14 illustrates a schematic configuration of a processing element according to example 8;

FIG. 15 illustrates a schematic configuration of a processing element according to example 9;

FIG. 16 illustrates a schematic configuration of a processing element according to example 10;

FIG. 17 illustrates a schematic configuration of a processing element according to example 11; and

FIG. 18 illustrates a schematic configuration of a processing element and a reconfigurable circuit including the same according to example 12.

### DESCRIPTION OF THE PREFERRED EMBODIMENTS

Reference may now be made in detail to embodiments of the present invention, examples of which are illustrated in the accompanying drawings, wherein like reference numerals refer to like elements throughout.

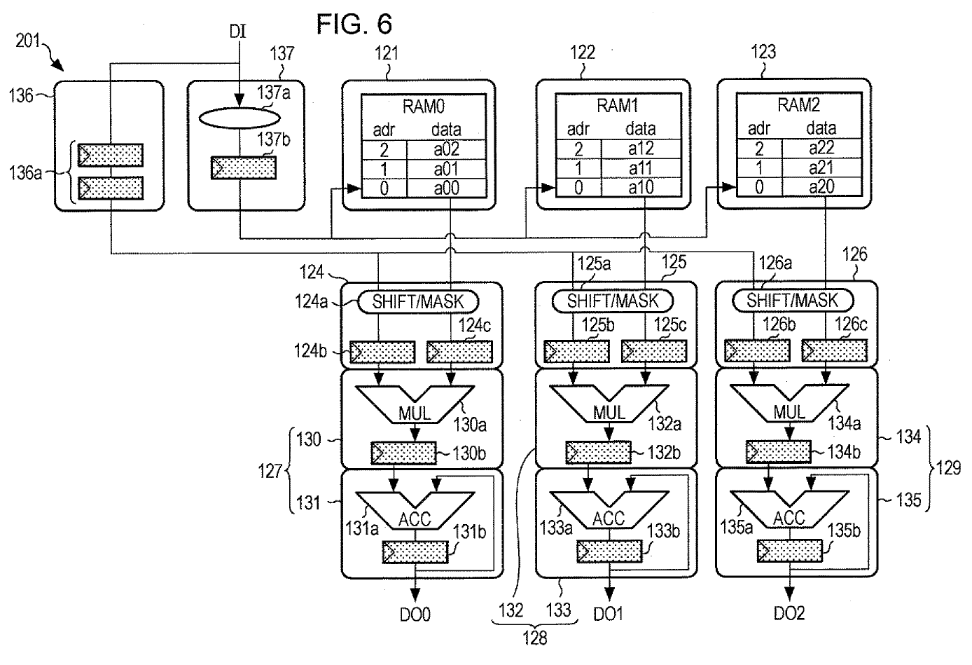

FIG. 6 illustrates a schematic configuration of the image processing reconfigurable LSI 201 performing image processing by using the spatial filter 111. As illustrated in FIG. 6, the conventional image processing reconfigurable LSI 201 includes the counter element 137 to count the number of pieces of input data DI, RAM elements 121, 122, and 123 to store part of the coefficients a00 to a22 of the spatial filter 111, shift/mask elements 124, 125, and 126 to perform a bit shift process and a bit mask process on the input data DI, and filter process elements 127, 128, and 129 to perform a filter process on the input data DI. Also, the image processing reconfigurable LSI 201 includes the data delay element 136 to adjust the timing when the input data ID is input to the shift/mask elements 124, 125, and 126.

The counter element 137 includes a counter 137a to count the number of inputs of input data DI and a register 137b to temporarily hold count data. The RAM element 121 includes a storage unit RAM0 to store the coefficients a00, a01, and a02 of the spatial filter 111. The coefficients a00, a01, and a02 are stored in the storage unit RAM0 while corresponding to addresses 0,1, and 2, respectively The RAM element 122 includes a storage unit RAM1 to store the coefficients a10, a11, and a12 of the spatial filter 111. The coefficients a10, a11, and a12 are stored in the storage unit RAM1 while corresponding to addresses 0, 1, and 2, respectively. The RAM element 123 includes a storage unit RAM2 to store the coefficients a20, a21, and a22 of the spatial filter 111. The coefficients a20, a21, and a22 are stored in the storage unit RAM2 while corresponding to addresses 0,1, and 2, respectively. Each of the RAM elements 121, 122, and 123 outputs the coefficient corresponding to the same address as that of the count data output from the counter element 137, among the coefficients a00 to a22.

The reconfigurable LSI 201 uses the spatial filter 111 of three rows and three columns, and thus each of the RAM elements 121, 122, and 123 stores three coefficients among the coefficients a00 to a22. The reconfigurable LSI 201 sequentially reads the coefficients a00 to a22 of the spatial filter 111 from the RAM elements 121, 122, and 123 by using three pieces of count data “0”, “1”, and “2” generated by the counter element 137.

The timings when the coefficients a00 to a22 are output from the RAM elements 121, 122, and 123 delay by the processing time in the counter element 137 and the RAM elements 121, 122, and 123 with respect to the timing when the input data DI is input to the counter element 137. Thus, the input data DI is input to the shift/mask elements 124, 125, and 126 via the data delay element 136. The data delay element 136 includes a register group 136a to delay the input data DI by the processing time. The register group 136a includes two registers connected to each other in series, for example.

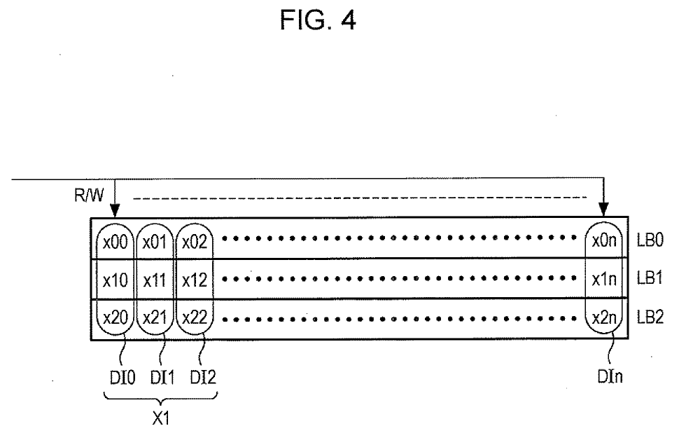

The shift/mask element 124 includes a shift/mask circuit 124a, a register 124b to temporarily hold the input data DI on which a bit shift process and a bit mask process have been performed by the shift/mask circuit 124a, and a register 124c to temporarily hold the coefficients a00, a01, and a02 output from the RAM element 121. The shift/mask circuit 124a performs a bit shift process on the input data DI having many bits so that the image data segments x00 to x0n (see FIG. 4) to be filter-processed can be filter-processed by the filter process element 127, and also performs a bit mask process on part of the input data DI on which a filter process is not to be performed by the filter process element 127.

The shift/mask elements 125 and 126 have the same configuration as that of the shift/mask element 124, that is, include shift/mask circuits 125a and 126a, registers 125b and 126b to hold the input data DI on which a bit shift process and a bit mask process have been done by the shift/mask circuits 125a and 126a, and registers 125c and 126c to hold the coefficients a10, a11, and a12 and the coefficients a20, a21, and a22 output from the RAM elements 122 and 123, respectively.

The input data DI0, DI1, and DI2 illustrated in FIG. 4 are sequentially input as pieces of input data DI. The input data DI is input to the data delay element 136. In the input data DI, the image data segments x00 to x0n stored in the line buffer LB0 serve as high bits on the MSB (most significant bit) side, the image data segments x10 to x1n stored in the line buffer LBI serve as intermediate bits, and the image data segments x20 to x2n stored in the line buffer LB2 serve as low bits on the LSB (least significant bits) side. The filter process elements 127, 128, and 129 perform a filter process on the image data segments of the low bits of the input data DI. Thus, in the input data DI input to each of the filter process elements 127, 128, and 129, the image data segments to be filter-processed are shifted on the LSB side. Thus, the shift/mask circuit 124a performs a bit shift process on the input data DI0 in order to shift the image data segment x00 to the right on the LSB side, and performs a bit mask process on the input data DI0 except the image data segment x00. Likewise, the shift/mask circuit 125a performs a bit shift process on the input data DI0 in order to shift the image data segment x10 to the right on the LSB side, and performs a bit mask process on the input data DI0 except the image data segment x10. The image data segment x20 is on the LSB side at the time of being input to the shift/mask element 126, and thus the shift/mask circuit 126a does not perform a bit shift process on the input data DI0 but performs a bit mask process on the input data DI0 except the image data segment x20.

The filter process element 127 includes a multiplier element 130 to multiply the image data segments x00 to x0n read from the line buffer LB0 illustrated in FIG. 4 by the coefficients a00, a01, and 02 read from the RAM element 121 and an accumulating adder element 131 to cumulatively add pieces of multiplication data generated by the multiplier element 130 in units of operation execution units. The multiplier element 130 includes a multiplier 130a to multiply the image data segments x00 to x0n by the coefficients a00, a01, and a02 and a register 130b to temporarily hold a multiplication result. The accumulating adder element 131 includes an adder 131a and a register 131b to temporarily hold addition data generated by the adder 131a. The adder 131a cumulatively adds the multiplication data output from the register 130b and the data held in the register 131b. Thus, the accumulating adder element 127 can cumulatively add pieces of multiplication data output from the multiplier element 130. Thus, the filter process element 127 can perform a process according to the following expression (4) on the image data segments x00 to x22 in the operation execution unit x11.

DO0=a00×x00+a01x01+a02×x02 (4)

The filter process element 128 has the same configuration as that of the filter process element 127. The filter process element 128 includes a multiplier element 132 to multiply the image data segments x10 to x1n read from the line buffer LB1 illustrated in FIG. 4 by the coefficients a10, a11, and a12 read from the RAM element 122 and an accumulating adder element 133 to cumulatively add the multiplication data generated by the multiplier element 132 in units of operation execution units. The filter process element 128 can perform a process according to the following expression (5) on the image data segments x00 to x22 in the operation execution unit x11, for example.

DO1=a10×x10+a11×x11+a12×x12 (5)

The filter process element 129 has the same configuration as that of the filter process elements 127 and 128. The filter process element 129 includes a multiplier element 134 to multiply the image data segments x20 to x2n read from the line buffer LB2 illustrated in FIG. 4 by the coefficients a20, a21, and a22 read from the RAM element 123 and an accumulating adder element 135 to cumulatively add the multiplication data generated by the multiplier element 134 in units of operation execution units. The filter process element 129 can perform a process according to the following expression (6) on the image data segments x00 to x22 in the operation execution unit x11, for example.

DO2=a20×x20+a21×x21+a22×x22 (6)

The image processing reconfigurable LSI 201 can add the output data DO0, DO1, and DO2 output from the filter process elements 127, 128, and 129, respectively, so as to calculate an image data segment Y11 expressed by the following expression (7) as a new image data segment of the target pixel x11 of the operation execution unit x11.

Y11=a00×x00+a01x01+a02×x02+a10×x10+a11×x11+a12×x12+a20×x20+a21×x21+a22×x22 (7)

The reconfigurable LSI 101 requires the RAM element 104 to store the memory data DI1 and read it therefrom and the counter element 103. In the reconfigurable LSI 101, the counter is used for both generating a read address signal to read the memory data DI1 and generating an enable signal ENB. If the counter is not used for these two purposes, the reconfigurable LSI 101 includes a counter element for generating a read address and a counter element for generating an enable signal ENB, independently. Also, the reconfigurable LSI 101 requires the data delay element 107 and the enable delay element 108 to adjust delay of the input data DI and the enable signal ENB. Furthermore, a network is disadvantageously occupied to connect these elements 103, 104, 107, and 108.

The image processing reconfigurable LSI 201 requires the RAM elements 121, 122, and 123 to store the coefficients a00 to a22 of the spatial filter 111 and read the coefficients therefrom, the counter element 137 to generate a read address signal, and the data delay element 136 to adjust delay of the input data DI. Furthermore, a network is disadvantageously occupied to connect these elements 121, 122, 123, 136, and 137.

As described above, the conventional reconfigurable LSI requires a processing element to store predetermined data and a processing element to adjust delay of data. Furthermore, the reconfigurable LSI requires a wiring area to connect these processing elements to each other. With this configuration, the conventional reconfigurable LSI has a problem that the chip size increases. Furthermore, the conventional reconfigurable LSI has a problem that a wiring load increases and that high-speed processing is difficult to perform.

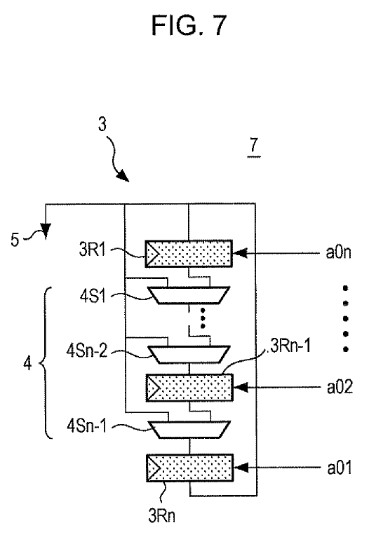

A processing element and a reconfigurable circuit including the same according to an embodiment are described with reference to FIGS. 7 to 18. The reconfigurable circuit according to the embodiment includes a processing element including a plurality of operation units and a circuit having a function equivalent to delay adjustment. The reconfigurable circuit according to the embodiment includes a plurality of configuration memories to determine a circuit configuration and a network configuration of the processing element and has a characteristic of being capable of changing the circuit configuration at several clock cycles. Hereinafter, the processing element and the reconfigurable circuit including the same according to the embodiment are described with reference to examples.

### EXAMPLE 1

A processing element and a reconfigurable circuit including the same according to example 1 are described with reference to FIG. 7. FIG. 7 illustrates a schematic configuration of a processing element 7 according to this example. As illustrated in FIG. 7, the processing element 7 includes a shift register 3 and a number-of-stages determining circuit 4. The shift register 3 includes n stages of registers 3R1 to 3Rn connected to each other in series. An output terminal of the register 3Rn in the last stage connects to an input terminal of the register 3R1 in the first stage, and coefficients a01 to a0n as held data are rotated among the n stages of registers 3R1 to 3Rn in synchronization with a clock signal. The number-of-stages determining circuit 4 determines the number of stages to be used among the n stages of registers 3R1 to 3Rn. The coefficients a01 to a0n as held data are coefficients of a spatial filter used for image processing, for example. In an initial state, the coefficient a01 is temporarily held in the register 3Rn in the last stage, the coefficient a02 is temporarily held in the register 3Rn-1 in the n-1-th stage, and the coefficient a0n is temporarily held in the register 3R1 in the first stage.

The number-of-stages determining circuit 4 includes selectors 4S1 to 4Sn-1, each being placed between adjoining registers of the n stages of registers 3R1 to 3Rn. In each of the selectors 4S1 to 4Sn-1, the coefficient as held data output from the register in an anterior stage in the adjoining registers and the coefficient as held data output from the register 3Rn in the last stage have been input. Each selector selects the coefficient as held data in any of the register in the anterior stage or the register 3Rn in the last stage and outputs the selected coefficient to the register in the posterior stage in the adjacent registers. Among the selectors placed between the registers, FIG. 7 illustrates the selector 4S1 placed between the register 3R1 in the first stage and a register in the second stage (not illustrated), the selector 4Sn-2 placed between a register in the n-2-th stage (not illustrated) and the register 3Rn-1 in the n-1-th stage, and the selector 4Sn-1 placed between the register 3Rn-1 in the n-1-th stage and the register 3Rn in the last stage.

For example, the selector 4Sn-1 is placed between the adjoining registers 3Rn-1 and 3Rn. The selector 4Sn-1 receives the coefficient a02 output from the register 3Rn-1 in the n-1-th stage (anterior stage) and the coefficient a01 of the register 3Rn in the last stage, selects one of the coefficients a01 and a02, and outputs the selected coefficient to the register 3Rn in the last stage (posterior stage). If the selector 4Si (1≦i≦n-1) among the selectors 4S1 to 4Sn-1 selects the held data in the register 3Rn in the last stage, the number-of-stages determining circuit 4 can determine the number of stages of registers to be used to be n-i stages. The number-of-stages determining circuit 4 is controlled by a control unit (not illustrated) provided in the reconfigurable circuit.

Next, performance of the processing element 7 is described with reference to FIG. 7. As illustrated in FIG. 7, the coefficients a01 to a0n as held data are set in the registers 3Rn to 3R1, respectively, and are temporarily held therein at initial setting. Also, at the initial setting, the number-of-stages determining circuit 4 allows all the selectors 4S1 to 4Sn-1 to select the held data in the registers 3R1 to 3Rn-1 so as to use n stages.

When a clock signal (not illustrated) rises after the initial setting, for example, in synchronization with a rising edge of the clock signal, the register 3R1 in the first stage outputs the coefficient a0n to the register in the second stage (not illustrated) via the selector 4S1, the register in the n-2-th stage (not illustrated) outputs the coefficient a03 (not illustrated) as held data to the register 3Rn-1 in the n-1-th stage via the selector 4Rn-2, the register 3Rn-1 in the n-1-th stage outputs the coefficient a02 to the register 3Rn in the last stage via the selector 4Sn-1, and the register 3Rn in the last stage outputs the coefficient a01 to the register 3R1 in the first stage and the selectors 4S1 to 4Sn-1. Accordingly, the coefficient a01 is held in the register 3R1 in the first stage, the coefficient a0n is held in the register in the second stage, the coefficient a03 is held in the register 3Rn-1 in the n-1-th stage, and the coefficient a02 is held in the register 3Rn in the last stage. During the above-described performance, the coefficient a01 output from the register 3Rn in the last stage is output from an output terminal 5 in synchronization with a rising edge of the clock signal.

When the clock signal rises again after the above-described performance, in synchronization with a rising edge of the clock signal, the register 3R1 in the first stage outputs the coefficient a01 to the register in the second stage (not illustrated) via the selector 4S1, the register in the n-2-th stage (not illustrated) outputs the coefficient a04 (not illustrated) to the register 3Rn-1 in the n-1-th stage via the selector 4Sn-2, the register 3Rn-1 in the n-1-th stage outputs the coefficient a03 to the register 3Rn in the last stage via the selector 4Sn-1, and the register 3Rn in the last stage outputs the coefficient a02 to the register 3R1 in the first stage. Accordingly, the coefficient a02 is held in the register 3R1 in the first stage, the coefficient a01 is held in the register in the second stage, the coefficient a04 is held in the register 3Rn-1 in the n-1-th stage, and the coefficient a03 is held in the register 3Rn in the last stage. During the above-described performance, the coefficient a02 output from the register 3Rn in the last stage is output from the output terminal S in synchronization with a rising edge of the clock signal.

The shift register 3 repeats the above-described performance in synchronization with rising edges of the clock signal, so that the coefficients a01 to a0n can be rotated among the registers 3R1 to 3Rn. After the clock signal rises n times, the coefficients a01 to a0n held in the registers 3R1 to 3Rn return to the original position at the initial setting.

For example, assume that setting is made in the number-of-stages determining circuit 4 so that only the selector 4Sn-2 selects the held data in the register 3Rn in the last stage at the initial setting. In this case, i=n-2, and thus the number of stages to be used among the n stages of registers 3R1 to 3Rn is two (=n-(n-2) stages).

When a clock signal rises after the initial setting, for example, in synchronization with a rising edge of the clock signal, the register 3Rn-1 in the n-1-th stage outputs the coefficient a02 to the register 3Rn in the last stage via the selector 4Sn-1, and the register 3Rn in the last stage outputs the coefficient a01 to the register 3R1 in the first stage and the selectors 4S1 to 4Sn-1. The selector 4Sn-1 is set to select the held data in the register 3Rn in the last stage and output the selected held data to the register 3Rn-1 in the n-1-th stage. Thus, during the above-described performance, the coefficient a01 output from the register 3Rn in the last stage is input to the register 3Rn-1 in the n-1-th stage via the selector 4Sn-1. Accordingly, the coefficient a01 is held in the register 3Rn-1 in the n-1-th stage, and the coefficient a02 is held in the register 3Rn in the last stage. During the above-described performance, the coefficient a01 output from the register 3Rn in the last stage is output from the output terminal 5 in synchronization with a rising edge of the clock signal.

When the clock signal rises again after the above-described performance, in synchronization with a rising edge of the clock signal, the register 3Rn-1 in the n-1-th stage outputs the coefficient a01 to the register 3Rn in the last stage via the selector 4Sn-1, and the register 3Rn in the last stage outputs the coefficient a02 to the register 3R1 in the first stage and the selectors 4S1 to 4Sn-1. The selector 4Sn-1 outputs the coefficient a02 to the register 3Rn-1 in the n-1-th stage. Accordingly, the coefficient a02 is held in the register 3Rn-1 in the n-1-th stage, and the coefficient a01 is held in the register 3Rn in the last stage. During the above-described performance, the coefficient a02 output from the register 3Rn in the last stage is output from the output terminal 5 in synchronization with a rising edge of the clock signal.

By repeating the above-described performance, the shift register 3 can rotate the coefficients a01 and a02 between the register 3Rn-1 in the n-1-th stage and the register 3Rn in the last stage in synchronization with rising edges of the clock signal. Also, the coefficient is input from the register 3Rn in the last stage to the registers 3R1 to 3Rn-2 and the selectors 4S1 to 4Sn-2. However, the coefficient held in the register 3Rn-2 in the n-2-th stage is not input to the register 3Rn-1 in the n-1-th stage, and thus the registers 3R1 to 3Rn-2 do not contribute to a shift operation of the coefficients as held data. In this way, the processing element 7 can determine the number of stages to be used in the shift register 3 by using the number-of-stages determining unit 4. With this configuration, when the number of pieces of held data to be rotated is small relative to the number of stages of the shift register 3, the number of stages to be used of the shift register 3 is set to the same number as that of the pieces of held data, so that the processing element 7 can continuously output the held data from the output terminal 5 in synchronization with the clock signal.

As described above, according to this example, the processing element 7 includes the shift register 3 having the registers 3R1 to 3Rn in many stages, so that the plurality of coefficients a01 to a0n can be held in the single processing element. Accordingly, the reconfigurable circuit according to this example including the processing element 7 can rotate the coefficients a01 to a0n by using a pipeline in the processing element 7. Thus, the reconfigurable circuit according to this example does not include the counter element 103 and the data delay element 107, unlike the conventional reconfigurable LSI 101. Accordingly, the space for the processing element in a semiconductor chip can be saved. Also, the reconfigurable circuit according to this example has a smaller number of processing elements, and thus the chip size can be reduced. Furthermore, in the reconfigurable circuit according to this example, a network is not occupied by a counter element unlike in the conventional circuit, and thus a wiring load is reduced and high-speed performance can be realized.

### EXAMPLE 2

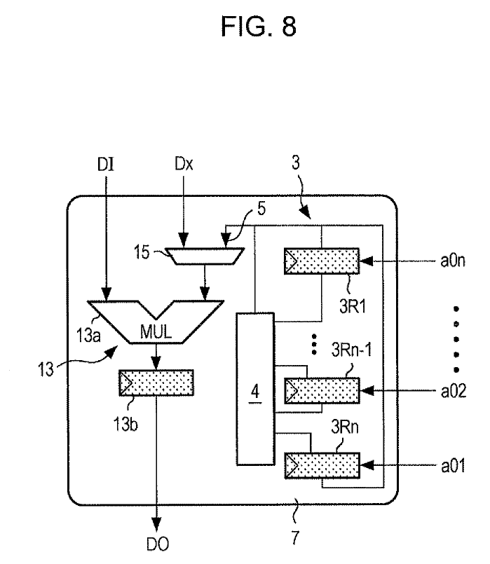

A processing element and a reconfigurable circuit including the same according to example 2 are described with reference to FIG. 8. FIG. 8 illustrates a schematic configuration of a processing element 7 according to this example. As illustrated in FIG. 8, the processing element 7 according to this example is characterized in including an operation unit having a multiplier circuit 13 in addition to the configuration of the processing element 7 according to example 1. The operation unit performs an operation on the coefficients a01 to a0n as held data, each being output from any of the n stages of registers 3R1 to 3Rn in synchronization with a clock signal, and input data DI input from the outside. In this example, the operation unit performs an operation on the held data output from the register 3Rn in the last stage and the input data DI. Alternatively, the operation may be performed on the held data output from any one of the registers 3R1 to 3Rn-1, not the register 3Rn in the last stage. In FIG. 8 and FIGS. 9 to 18, the number-of-stages determining circuit 4 is illustrated as a single block, but includes n-1 selectors 4S1 to 4Sn-1 as in the configuration illustrated in FIG. 7.

Referring back to FIG. 8, the multiplier circuit 13 provided in the operation unit includes a multiplier 13a to multiply the coefficients a01 to a0n by the input data DI and a register 13b to temporarily hold multiplication data output from the multiplier 13a and output the data.

The processing element 7 includes a selector 15 to select the coefficients a01 to a0n sequentially output from the output terminal 5 and predetermined data Dx input from the outside and output them to the multiplier circuit 13.

Next, performance of the processing element 7 according to this example is described with reference to FIG. 8. The shift register 3 and the number-of-stages determining circuit 4 perform in the same manner as in example 1. That is, the shift register 3 sequentially outputs the coefficients a01 to a0n from the output terminal 5 in synchronization with rising edges of the clock signal. For example, assume that the selector 15 is set to select the coefficients a01 to a0n from the output terminal 5 at initial setting. In this case, the selector 15 sequentially outputs the coefficients a01 to a0n from the output terminal 5 to the multiplier 13a. The input data DI is input to the multiplier 13a at every clock cycle in synchronization with output of the coefficients a01 to a0n form the output terminal 5. The multiplier 13a sequentially multiplies pieces of the input data DI by the coefficients a01 to a0n and sequentially outputs pieces of multiplication data to the register 13b. The register 13b temporarily holds the multiplication data. Then, the register 13b outputs the multiplication data held therein as output data DO to the outside of the processing element 7 in synchronization with a rising edge of the clock signal.

Assume that the selector 15 is set to select the data Dx from the outside at the initial setting. In this case, for example, the multiplier circuit 13 multiplies the input data DI and the data Dx input to the multiplier 13a in synchronization with a rising edge of the clock signal and outputs multiplication data as output data DO from the register 13b to the outside of the processing element 7.

As described above, according to this example, the processing element 7 includes the shift register 3 having the registers 3R1 to 3Rn in many stages and the multiplier circuit 13. With this configuration, the reconfigurable circuit according to this example including the processing element 7 can rotate the coefficients a01 to a0n by using a pipeline in the processing element 7 and multiply the coefficients a01 to a0n by the input data DI. Thus, the reconfigurable circuit can perform an operation in the single processing element, so that timing adjustment between the input data DI and the coefficients a01 to a0n is not required. Accordingly, the reconfigurable circuit according to this example does not include the counter element 103 and the data delay element 107, unlike the conventional reconfigurable LSI 101. Thus, the processing element 7 and the reconfigurable circuit including the same according to this example have the same advantages as those in example 1.

### EXAMPLE 3

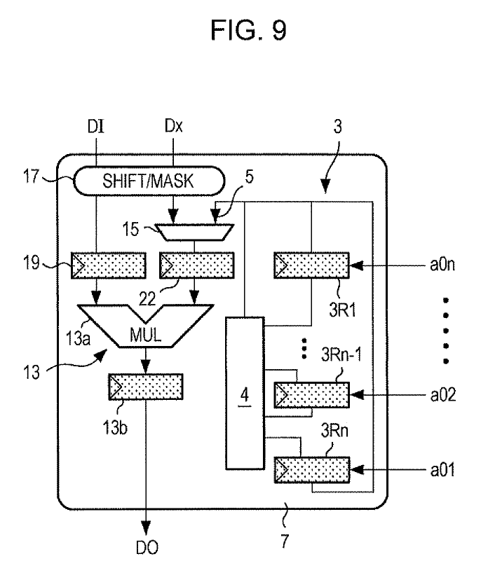

A processing element and a reconfigurable circuit including the same according to example 3 are described with reference to FIG. 9. FIG. 9 illustrates a schematic configuration of a processing element 7 according to this example. As illustrated in FIG. 9, the processing element 7 according to this example is characterized in including a shift/mask circuit 17 and registers 19 and 22 in addition to the configuration of the processing element 7 according to example 2. The shift/mask circuit 17 performs a bit shift process and a bit mask process on input data DI and outputs the input data DI to the multiplier circuit 13 via the register 19. The register 19 holds the input data DI output from the shift/mask circuit 17 and outputs the input data DI to the multiplier circuit 13 in synchronization with a rising edge of a clock signal. The register 22 holds the coefficients a01 to a0n or data Dx output from the selector 15. The register 22 outputs the coefficients a01 to a0n or the data Dx to the multiplier circuit 13 in synchronization with rising edges of the clock signal. The register 22 is placed for timing adjustment between the input data DI output from the register 19 and the coefficients a01 to a0n or the data Dx output from the selector 15.

The shift/mask circuit 17 performs a bit shift process on the input data DI so that the multiplier circuit 13 can multiply the input data DI by the coefficients a01 to a0n or the data Dx, and also performs a bit mask process on part of the input data DI that is not multiplied in the multiplier circuit 13. For example, assume that the multiplier circuit 13 has a function of performing operation on low 8 bits on the LSB side of the input data DI and the coefficients a01 to a0n or the data Dx. Also, assume that the input data DI is composed of 24 bits and that the high 8 bits on the MSB side are to be operated. In this case, the shift/mask circuit 17 shifts the high 8 bits of the input data DI to the right to the low 8 bits on the LSB side and performs a mask process on high 18 bits. Accordingly, the data to be operated is bit-shifted to the low 8 bits, so that the multiplier circuit 13 can perform operation on the coefficients a01 to a0n or the data Dx and the data to be operated in the input data DI.

The performance of the processing element 7 according to this example is the same as in example 2 except that the shift/mask circuit 17 performs a bit shift process and a bit mask process on the input data DI.

As described above, according to this example, the processing element 7 includes the shift/mask circuit 17 and thus can perform operation on some of many bits of the input data DI and the coefficients a01 to a0n or the data Dx. The reconfigurable circuit including the processing element 7 according to this example does not include the counter element 103 and the data delay element 107, unlike the conventional reconfigurable LSI 101. Thus, the reconfigurable circuit according to this example can have the same advantages as those in examples 1 and 2.

### Example 4

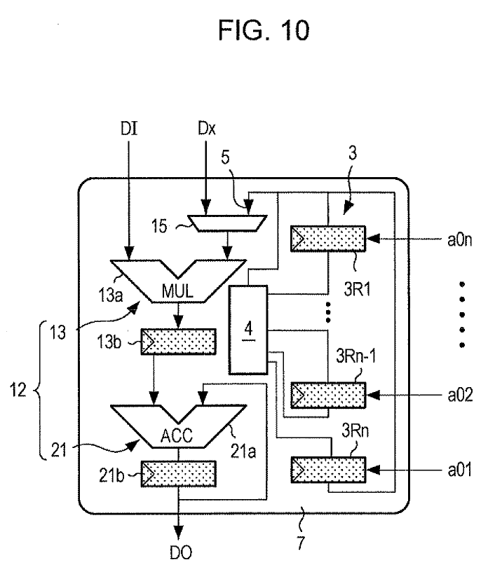

A processing element and a reconfigurable circuit including the same according to example 4 are described with reference to FIG. 10. FIG. 10 illustrates a schematic configuration of a processing element 7 according to this example. As illustrated in FIG. 10, the processing element 7 includes an accumulating adder circuit 21, provided in an operation unit 12, to cumulatively add pieces of multiplication data output from the multiplier circuit 13, in addition to the configuration of the processing element 7 according to example 2.

The accumulating adder circuit 21 includes an adder 21a to which the multiplication data is input and a register 21b to temporarily hold addition data generated by the adder 21a and output the addition data as output data DO to the outside of the processing element 7. The adder 21a adds the multiplication data output from the multiplier circuit 13 and the addition data temporarily held in the register 21b. Accordingly, the accumulating adder circuit 21 can cumulatively add pieces of the multiplication data. The register 21b outputs the output data DO in synchronization with a rising edge of a clock signal.

Next, performance of the processing element 7 according to this example is described with reference to FIG. 10. The multiplier circuit 13 performs in the same manner as in the processing element 7 according to example 2 and outputs multiplication data to the accumulating adder circuit 21. The adder 21a of the accumulating adder circuit 21 adds the multiplication data and the data held in the register 21b and outputs addition data to the register 21b. The register 21b holds the addition data. Then, the register 21b outputs the addition data held therein to the adder 21a and also outputs the addition data as output data DO to the outside of the processing element 7 in synchronization with a next rising edge of the clock signal. In synchronization with the clock signal, the multiplication data is input from the multiplier circuit 13 to the adder 21a. The adder 21a adds the multiplication data and the data output from the register 21b and outputs addition data to the register 21b. The processing element 7 repeats the above-described performance and thus functions as a product-sum element.

As described above, the processing element 7 according to this example can perform a product-sum operation on the input data DI and the coefficients a01 to a0n. Thus, the reconfigurable circuit including the processing element 7 according to this example does not include the counter element 103 and the data delay element 107, unlike the conventional reconfigurable LSI 101. Thus, the processing element 7 and the reconfigurable circuit including the same according to this example can have the same advantages as those in examples 1 to 3.

### EXAMPLE 5

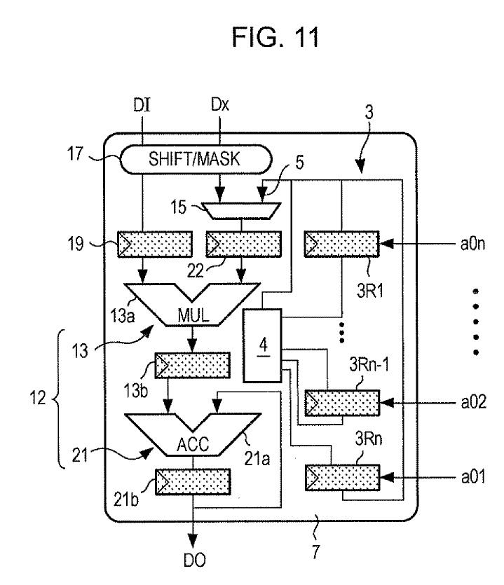

A processing element and a reconfigurable circuit including the same according to example 5 are described with reference to FIG. 11. FIG. 11 illustrates a schematic configuration of a processing element 7 according to this example. As illustrated in FIG. 11, the processing element 7 according to this example includes the shift/mask circuit 17 and the registers 19 and 22, in addition to the configuration according to example 4. The shift/mask circuit 17 has the same function as that of the shift/mask 17 provided in the processing element 7 according to example 3. Thus, the processing element 7 according to this example can cumulatively add some of many bits of the input data DI and the coefficients a01 to a0n or data Dx. The performance of the processing element 7 according to this example is the same as that in example 4 except that a shift/mask process is performed on the input data DI.

As described above, according to this example, the processing element 7 can cumulatively add some of many bits of the input data DI and the coefficients a01 to a0n. The reconfigurable circuit including the processing element 7 does not include the counter element 103 and the data delay element 107, unlike the conventional reconfigurable LSI 101. Thus, the processing element 7 and the reconfigurable circuit according to this example can have the same advantages as those in examples 1 to 4.

### EXAMPLE 6

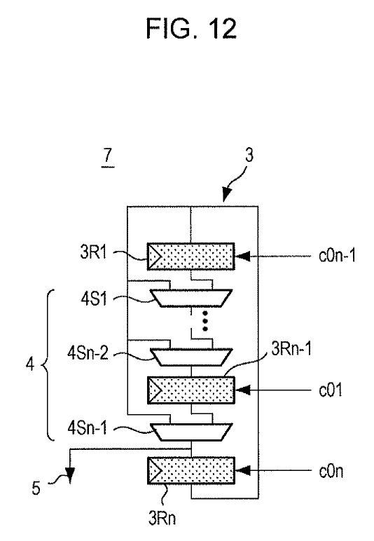

A processing element and a reconfigurable circuit including the same according to example 6 of the embodiment are described with reference to FIG. 12. FIG. 12 illustrates a schematic configuration of a processing element 7 according to this example. As illustrated in FIG. 12, the processing element 7 according to this example has the same configuration as that of the processing element 7 according to example 1 except that the output position of the held data output from the shift register 3 is different and that pieces of held data rotated among the n stages of registers 3R1 to 3Rn are different.

Pieces of held data c01 to c0n are used as control signal data to control an operation unit (not illustrated). For example, each of the pieces of held data c01 to c0n-1 is data of “0” composed of several bits, and the held data c0n is data of “1” composed of several bits. The shift register 3 can output the held data of “1” from the output terminal 5 at every n clock cycles. In FIG. 12, the held data to be input to the register 3Rn in the last stage among the pieces of held data c01 to c0n is output. The pieces of held data c01 to c0n output from the output terminal 5 may be input to the registers 3R1 to 3Rn-1, not to the register 3Rn in the last stage.

The performance of the processing element 7 according to this example is the same as that in example 1 except that the output position of the pieces of held data c01 to c0n output from the shift register 3 is different.

As described above, according to this example, the processing element 7 includes the shift register 3 having the registers 3R1 to 3Rn in many stages, and thus can rotate the pieces of held data c01 to c0n in the single processing element. Accordingly, the reconfigurable circuit including the processing element 7 uses a pipeline in the processing element 7 as a delay device so as to allow the pieces of held data c01 to c0n used as control signal data (e.g., enable signal) to propagate. Thus, the reconfigurable circuit according to this example does not include the counter element 103 and the enable delay element 108, unlike the conventional reconfigurable LSI 101. With this configuration, the space for the processing element in a semiconductor chip can be saved. Also, the reconfigurable circuit can be miniaturized because the number of processing elements is reduced. Furthermore, in the reconfigurable circuit according to this example, a network is not occupied by a counter element and so on unlike in the conventional circuit, and thus a wiring load is reduced and high speed performance can be realized.

### EXAMPLE 7

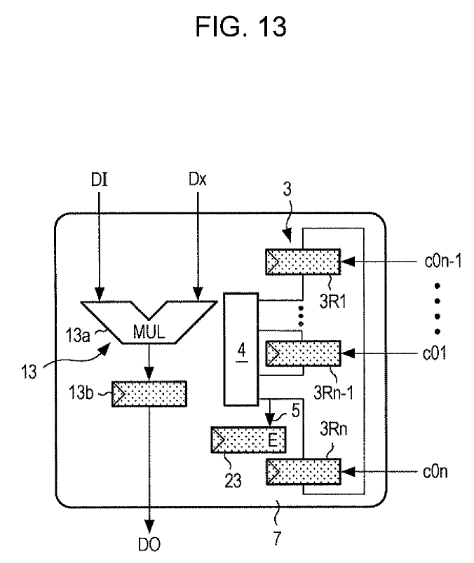

A processing element and a reconfigurable circuit including the same according to example 7 of the embodiment are described with reference to FIG. 13. FIG. 13 illustrates a schematic configuration of a processing element 7 according to this example. As illustrated in FIG. 13, the processing element 7 according to this example includes a register 23 controlled by the pieces of held data c01 to c0n output from the shift register 3 via the output terminal 5, in addition to the configuration according to example 6. The pieces of held data are input to a control terminal E of the register 23. The register 23 resets the held data therein based on the value of the held data.

Furthermore, the processing element 7 includes the multiplier circuit 13 to perform operation on the input data DI and predetermined data Dx input from the outside. The multiplier circuit 13 includes the multiplier 13a to multiply the input data DI by the predetermined data Dx and the register 13b to temporarily hold multiplication data output from the multiplier 13a and output the multiplication data as output data DO to the outside of the processing element 7.

Next, performance of the processing element 7 according to this example is described with reference to FIG. 13. The shift register 3 performs in the same manner as in example 6. For example, the shift register 3 outputs the data c01 held in the register 3Rn-1 to the control terminal E of the register 23 via the output terminal 5 in synchronization with a rising edge of a clock signal. The input data DI and the data Dx input from the outside are input to the multiplier 13a of the multiplier circuit 13 in synchronization with a rising edge of the clock signal. The multiplier 13a multiplies the input data DI by the data Dx and outputs multiplication data to the register 13b. The register 13b holds the multiplication data and outputs it as output data DO to the outside of the processing element 7. The above-described performance is repeated, and the register 13b outputs the output data DO to the outside of the processing element 7 in synchronization with the clock signal. When the held data of “1” is input to the control terminal E, the register 23 resets the held data to “0”. That is, the register 23 resets the held data at every n clock cycles.

As described above, according to this example, the processing element 7 includes the shift register 3 and the multiplier circuit 13. Thus, the reconfigurable circuit including the processing element 7 according to this example does not include the counter element 103 and the enable delay element 108, unlike the conventional reconfigurable LSI 101. Thus, the reconfigurable circuit according to this example can have the same advantages as those in example 6.

### EXAMPLE 8

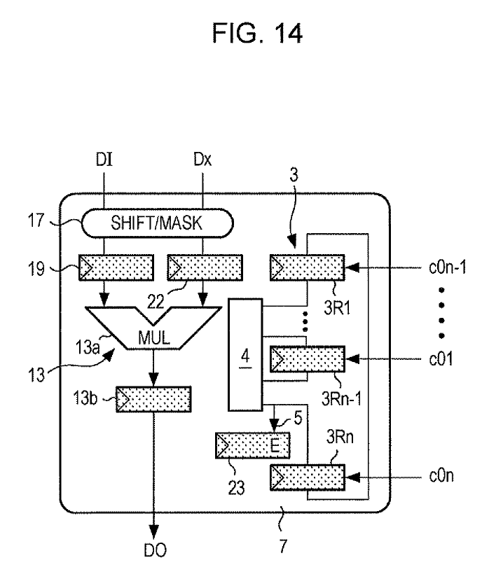

A processing element and a reconfigurable circuit including the same according to example 8 are described with reference to FIG. 14. FIG. 14 illustrates a schematic configuration of a processing element 7 according to this example. As illustrated in FIG. 14, the processing element 7 according to this example includes the shift/mask circuit 17 and the registers 19 and 22, in addition to the configuration of the processing element 7 according to example 7. The shift/mask circuit 17 and the registers 19 and 22 have the same configuration and function as those of the shift/mask circuit 17 and the registers 19 and 22 according to example 3.

The performance of the processing element 7 according to this example is the same as that in example 7 except that the shift/mask circuit 17 performs a bit shift process and a bit mask process on the input data DI.

As described above, according to this example, the processing element 7 includes the shift/mask circuit 17 and thus can multiply some of many bits of the input data DI by data Dx. The reconfigurable circuit including the processing element 7 according to this example does not include the counter element 103 and the enable delay element 108, unlike the conventional reconfigurable LSI 101. Thus, the reconfigurable circuit according to this example can have the same advantages as those in examples 6 and 7.

### EXAMPLE 9

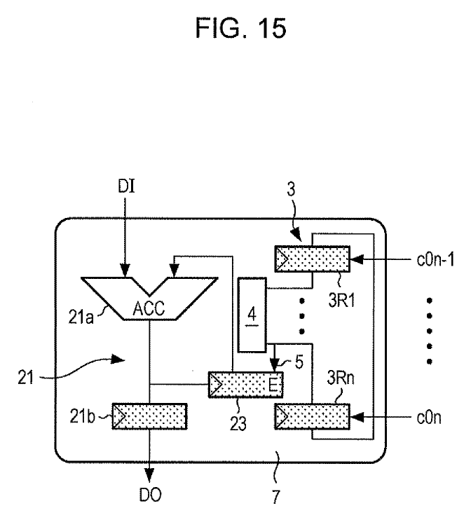

A processing element and a reconfigurable circuit including the same according to example 9 of the embodiment are described with reference to FIG. 15. FIG. 15 illustrates a schematic configuration of a processing element 7 according to this example. As illustrated in FIG. 15, the processing element 7 according to this example includes an operation unit to perform operation on externally input data DI based on pieces of held data c01 to c0n each output from any one of the n stages of registers 3R1 to 3Rn in synchronization with a clock signal, in addition to the configuration of the processing element 7 according to example 6. The operation unit performs operation on the input data DI based on the held data input to the register 3Rn in the last stage.

The operation unit includes the accumulating adder circuit 21 in which the number of accumulations of the input data ID is controlled based on the pieces of held data c01 to c0n. The accumulating adder circuit 21 includes the adder 21a to cumulatively add pieces of the input data DI, the register 21b to temporarily hold addition data generated by the adder 21a and output the data as output data DO to the outside of the processing element 7, and the register 23 controlled by the pieces of held data c01 to c0n. The processing element 7 includes the accumulating adder circuit 21 and thus has a function as an accumulating adder element.

The register 23 temporarily holds addition data output from the adder 21a and outputs the addition data to the adder 21a in synchronization with a rising edge of a clock signal. The adder 21a adds the addition data output from the register 23 and the input data DI, so that the accumulating adder circuit 21 can cumulatively add pieces of the input data. The register 23 can reset the data held therein based on the pieces of held data c01 to c0n. Furthermore, the register 23 can determine whether the output data DO is to be output from the register 21b based on the pieces of held data c01 to c0n. In this way, the accumulating adder circuit 21 can control output timing of operated data based on the pieces of held data c01 to c0n. The accumulating adder circuit 21 can control the number of accumulations of the input data DI and output timing of the addition data based on the pieces of held data c01 to c0n. When the held data of “1” is input to the control terminal E, the register 21b outputs the addition data accumulated so far as output data DO.

Next, performance of the processing element 7 according to this example is described with reference to FIG. 15. As illustrated in FIG. 15, the pieces of held data c01 to c0n-1 of “0” are set to the registers 3Rn-1 (not illustrated) to 3R1 and the held data c0n of “1” is held in the register 3Rn at initial setting. Also, in order to use n stages, setting is made in the number-of-stages determining circuit 4 so that all selectors 4S1 to 4Sn-1 (not illustrated) select the pieces of held data in the registers 3R1 to 3Rn-1, respectively, at the initial setting. The register 23 is set to hold the data of “0”.

The shift register 3 performs in the same manner as in the shift register 3 according to example 6. For example, the shift register 3 sequentially outputs the pieces of held data c01 to c0n to the register 23 via the output terminal 5 in synchronization with rising edges of the clock signal. The pieces of held data c01 to c0n-1 are data of “0” and the held data c0n is data of “1”. Thus, the shift register 3 outputs the pieces of held data c01 to c0n-1 of “0” to the register 23 during n-1 clock cycles from the initial setting, and outputs the held data c0n of “1” to the register 23 at the n-th clock. Then, the shift register 3 outputs the held data c0n of “1” to the register 23 at every n clock cycles.

On the other hand, each piece of the input data DI is input to the adder 21a in synchronization with a rising edge of the clock signal. The accumulating adder circuit 21 outputs addition data generated by adding first input data DI and the data of “0” held in the register 23 to the registers 21b and 23 in synchronization with output timing of the held data c01. For example, if the held data output from the shift register 3 and the number-of-stages determining circuit 4 is “0”, the register 23 holds the addition data and outputs it to the adder 21a at a next rising edge of the clock signal. The register 21b outputs the addition data as output data DO to the outside of the processing element 7.

The processing element 7 repeats the above-described performance, and the accumulating adder circuit 21 cumulatively adds first to n-th input data DI. Assuming that the first to n-th input data DI are x01 to x0n, the accumulating adder circuit 21 outputs the output data DO=x01+x02+ . . . +x0n after n clock cycles. At the same time when cumulatively-added data to the n-th input data DI is input to the register 23, the held data c0n of “1” is input from the shift register 3 and the number-of-stages determining circuit 4 to the control terminal E of the register 23. Accordingly, the register 23 resets the held data to “0”, the value at the initial setting. Since the data held in the register 23 is reset to “0” at every n clock cycles, the processing element 7 can cumulatively add n pieces of input data DI. According to the above description, the register 21b is controlled to output data DO every time addition data is input thereto. However, the register 21b may be controlled to output cumulatively-added first to n-th input data DI as output data DO every time held data of “1” is input to the control terminal E of the register 23, that is, at every n clock cycles.

As described above, in the processing element 7 according to this example, the pieces of held data c01 to c0n as control signals propagate through a pipeline in the processing element 7, and data can be accumulated and output at arbitrary timing and arbitrary times. Thus, the processing element 7 functions as an accumulating adder element. The reconfigurable circuit including the processing element 7 can perform operation in the single processing element, and thus timing adjustment between the input data DI and the coefficients a01 to a0n is not required. Accordingly, the reconfigurable circuit according to this example does not include the counter element 103 and the enable delay element 108, unlike the conventional reconfigurable LSI 101. Thus, the reconfigurable circuit according to this example has the same advantages as those in examples 6 to 8.

### EXAMPLE 10

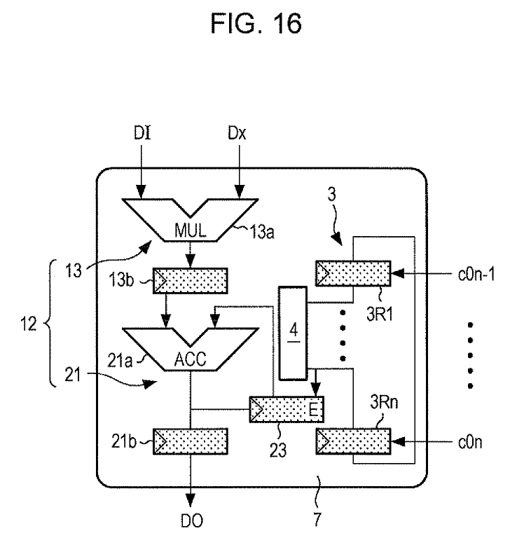

A processing element and a reconfigurable circuit including the same according to example 10 of the embodiment are described with reference to FIG. 16. FIG. 16 illustrates a schematic configuration of a processing element 7 according to this example. As illustrated in FIG. 16, the processing element 7 according to this example is characterized in including the operation unit 12 having the multiplier circuit 13 according to example 7 and the accumulating adder circuit 21 according to example 9, in addition to the configuration of the processing element 7 according to example 6. With this configuration, the operation unit 12 can cumulatively add pieces of multiplication data each being generated by multiplying input data DI by data Dx. Thus, the processing element 7 has a function as a product-sum operation element.

The configuration and performance of the processing element 7 according to this example are the same as those of the processing element 7 according to example 9 except that the pieces of data added in the accumulating adder circuit 21 are pieces of multiplication data output from the multiplier circuit 13, and thus the corresponding description is omitted.

As described above, the processing element 7 according to this example functions as a product-sum operation element. Thus, the reconfigurable circuit including the processing element 7 according to this example does not include the counter element 103, the data delay element 107, and the enable delay element 108, unlike the conventional reconfigurable LSI 101. Thus, the reconfigurable circuit according to this example can have the same advantages as those in examples 6 to 9.

### EXAMPLE 11

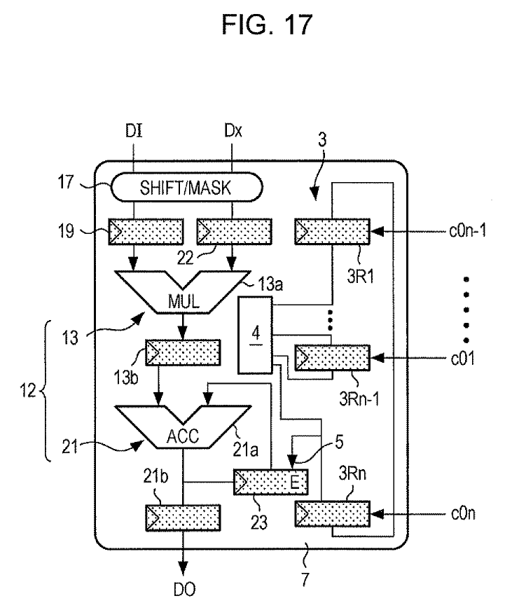

A processing element and a reconfigurable circuit including the same according to example 11 of the embodiment are described with reference to FIG. 17. FIG. 17 illustrates a schematic configuration of a processing element 7 according to this example. As illustrated in FIG. 17, the processing element 7 according to this example is characterized in including the shift/mask circuit 17 and the registers 19 and 22, in addition to the configuration of the processing element 7 according to example 10. The shift/mask circuit 17 and the registers 19 and 22 have the same function as that in example 8. Thus, the processing element 7 according to this example can cumulatively add some of many bits of input data DI and data Dx. The performance of the processing element 7 according to this example is the same as that in example 10 except that a bit shift process and a bit mask process can be performed on the input data DI.

As described above, according to this example, the processing element 7 can perform a product-sum operation on some of many bits of the input data DI and the data Dx. The reconfigurable circuit including the processing element 7 according to this example does not include the counter element 103, the data delay element 107, and the enable delay element 108, unlike the conventional reconfigurable LSI 101. Thus, the reconfigurable circuit according to this example can have the same advantages as those in examples 6 to 10.

### EXAMPLE 12

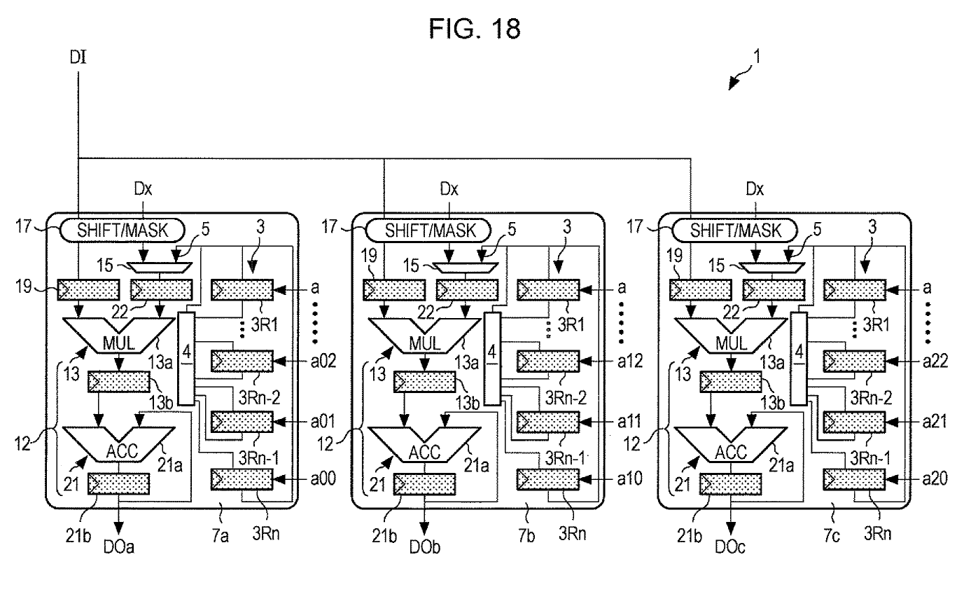

A processing element and a reconfigurable circuit including the same according to example 12 of the embodiment are described with reference to FIG. 18. FIG. 18 illustrates a schematic configuration of processing elements 7a, 7b, and 7c and a reconfigurable circuit 1 including the elements according to this example. The reconfigurable circuit 1 according to this example has the same function as that of the conventional image processing reconfigurable LSI 201. As illustrated in FIG. 18, the reconfigurable circuit 1 according to this example includes the processing elements 7a, 7b, and 7c of which input terminals for input data DI are mutually connected. Each of the processing elements 7a, 7b, and 7c has the same configuration as that of the processing element 7 according to example 5. In each of the processing elements 7a, 7b, and 7c, setting is made in the number-of-stages determining circuit 4 at initial setting so that the registers 3Rn-2, 3Rn-1, and 3Rn in three stages among the registers 3R1 to 3Rn in n stages of the shift register 3 are used.

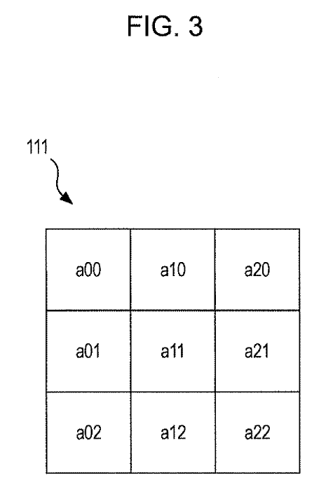

At the initial setting, the coefficients a02, a01, and a00 of the spatial filter 111 illustrated in FIG. 3 are held as held data in the registers 3Rn-2, 3Rn-1, and 3Rn of the processing element 7a, respectively. Also, the coefficients a12, a11, and a10 of the spatial filter 111 illustrated in FIG. 3 are held as held data in the registers 3Rn-2, 3Rn-1, and 3Rn of the processing element 7b, respectively. Also, the coefficients a22, a21 and a20 of the spatial filter 111 illustrated in FIG. 3 are held as held data in the registers 3Rn-2, 3Rn-1, and 3Rn of the processing element 7c, respectively. In the other registers 3R1 to 3Rn-3 (not illustrated) of each of the processing elements 7a, 7b, and 7c, coefficients “a” not related to the coefficients of the spatial filter 111 are held at the initial setting. The configuration of each of the processing elements 7a, 7b, and 7c is the same as that of the processing element 7 according to example 5.

Next, performance of the processing elements 7a, 7b, and 7c and the reconfigurable circuit 1 including the same according to this example is described with reference to FIG. 18. As illustrated in FIG. 18, setting is made in each of the number-of-stages determining circuits 4 of the processing elements 7a, 7b, and 7c at the initial setting so that only a selector 4Sn-3 (not illustrated) selects the held data in the register in the anterior stage (register 3Rn-3, not illustrated) in order to use three stages. Also, as illustrated in FIG. 18 the coefficients a00 to a22 of the spatial filter 111 are held in the registers 3Rn-2, 3Rn-1, and 3Rn of the processing elements 7a, 7b, and 7c. Furthermore, each of the selectors 15 of the processing elements 7a, 7b, and 7c is set to select output data of the register 3Rn in the last stage. The data held in the registers 21b of the processing elements 7a, 7b, and 7c is set to “0” composed of 8 bits.

When a clock signal rises after the initial setting, for example, in synchronization with a rising edge of the clock signal, the registers 3Rn in the last stages of the processing elements 7a, 7b, and 7c output the coefficients a00, a10, and a20 to the registers 3Rn-2 in the n-2-th stages via the selectors 4Sn-3, respectively, the registers 3Rn-1 in the n-1-th stages output the coefficients a01, a11, and a21 to the registers 3Rn in the last stages via the selectors 4Sn-1 (not illustrated), respectively, and the registers 3Rn-2 in the n-2-th stages output the coefficients a02, a12, and a22 to the registers 3Rn-1 in the n-1-th stages via the selectors 4Sn-2 (not illustrated), respectively. Also, in synchronization with a rising edge of the clock signal, the registers 3Rn in the last stages output the coefficients a00, a10, and a20 to the selectors 15 via the output terminals 5, respectively. The selectors 15 output the coefficients a00, a10, and a20 to the registers 22, respectively.

At the same time when the coefficients a00, a10, and a20 are output from the registers 3Rn in the last stages, the input data DI0 composed of the image data segments x00, x10, and x20 illustrated in FIG. 4 is input to the shift/mask circuits 17 of the processing elements 7a, 7b, and 7c. For example, each of the image data segments x00 to x2n illustrated in FIG. 4 is composed of 8 bits. In the input data DI0, the high 8 bits on the MSB side correspond to the image data segment x00, the intermediate 8 bits correspond to the image data segment x10, and the low 8 bits on the LSB side correspond to the image data segment x20. The input data DI0 has 24 bits in total. The input data DI1 to DIn illustrated in FIG. 4 have 24 bits, as the input data DI0. The high 8 bits correspond to 01 to x0n, the intermediate 8 bits correspond to x11 to x1n, and the low 8 bits correspond to x21 to x2n.

Assume that each of the multiplier circuits 13 has a function of performing operation on the low 8 bits on the LSB side of the input data DI and the 8-bit coefficients a00 to a0n. The shift/mask circuit 17 of the processing element 7a shifts 16 bits of the input data DI0 to the right, shifts the image data segment x00 to the low 8 bits, and then performs a bit mask process on the high 18 bits. The shift/mask circuit 17 of the processing element 7b shifts 8 bits of the input data DI0 to the right, shifts the image data segment x10 to the low 8 bits, and then performs a bit mask process on the high 18 bits. The shift/mask circuit 17 of the processing element 7c does not perform a bit shift process and performs a bit mask process on the high 18 bits. Accordingly, the image data segments x00, x10, and x20 to be operated are shifted to the low 8 bits. The pieces of input data DI0 on which a bit shift process and a bit mask process have been done in the shift/mask circuits 17 are output to the registers 19, respectively.

After a clock signal rises again after the above-described performance, in synchronization with a rising edge of the clock signal, the registers 19 of the processing elements 7a, 7b, and 7c output the input data DI0 to the multipliers 13a, and the registers 22 output the coefficients a00, a10, and a20 to the multipliers 13a, respectively. The multipliers 13a of the processing elements 7a, 7b, and 7c multiply the input data DI0 by the coefficients a00, a10, and a20, respectively, and output multiplication data to the registers 13b. The registers 13b of the processing elements 7a, 7b, and 7c hold the multiplication data.

The shift reregisters 3 perform in synchronization with a rising edge of the clock signal Accordingly, the coefficients a01, a11, and a21 are held in the registers 3Rn-2 in the n-2-th stages, the coefficients a00, a10, and a20 are held in the registers 3Rn-1 in the n-1-th stages, and the coefficients a02, a12, and a22 are held in the registers 3Rn in the last stages. At that time, the coefficients a01, a11, and a21 output from the register 3Rn in the last stages are held in the registers 22, respectively. Furthermore, a bit shift process and a bit mask process are performed by the shift/mask circuits 17 on the input data DI1 (see FIG. 4) that is input in synchronization with a rising edge of the clock signal, and the input data DI1 is held in each of the registers 19.

When the clock signal rises again after the above-described performance, in synchronization with a rising edge of the clock signal, pieces of multiplication data output from the registers 13b of the processing elements 7a, 7b, and 7c are output to the adders 21a, respectively. Since the registers 21b hold data of “0”, the adders 21a add the multiplication data and the data of “0” and output addition data to the registers 21b. The registers 21b of the processing elements 7a, 7b, and 7c hold the addition data output from the adders 21a as held addition data. For example, in the processing element 7a, the held addition data is a00×x00.

In synchronization with a rising edge of the clock signal, the registers 19 of the processing elements 7a, 7b, and 7c output the input data DI1 to the multipliers 13a, and the registers 22 output the coefficients a01, a11, and a21 to the multipliers 13a. The multipliers 13a of the processing elements 7a, 7b, and 7c multiply the input data DI1 by the coefficients a01, a11, and a21, respectively, and output multiplication data to the registers 13b. The registers 13b of the processing elements 7a, 7b, and 7c hold the multiplication data.

The shift registers 3 perform in synchronization with a rising edge of the clock signal. Accordingly, the coefficients a02, a12, and a22 are held in the registers 3Rn-2 in the n-2-th stages, the coefficients a01, a11, and a21 are held in the registers 3Rn-1 in the n-1-th stages, and the coefficients a00, a10, and a20 are held in the registers 3Rn in the last stages. At that time, the coefficients a02, a12, and a22 output from the registers 3Rn in the last stages are held in the registers 22. Furthermore, a bit shift process and a bit mask process are performed by the shift/mask circuits 17 on the input data DI2 (see FIG. 4) that is input in synchronization with a rising edge of the clock signal and the input data DI2 is held in the registers 19.

When the clock signal rises again after the above-described performance, the registers 21b of the processing elements 7a, 7b, and 7c output the data held therein as output data DOa, DOb, and DOc to the outside of the processing elements 7a, 7b, and 7c, in synchronization with a rising edge of the clock signal.

In synchronization with a rising edge of the clock signal, the registers 13b of the processing elements 7a, 7b, and 7c output multiplication data held therein to the adders 21a, and the registers 21b output addition data held therein to the adders 21a. The adders 21a add the input multiplication data and the held addition data and output the generated data to the registers 21b. The registers 21b of the processing elements 7a, 7b, and 7c hold the addition data output from the adders 21a as held addition data. For example, in the processing element 7a, the held addition data is a00×x00+a01×x01.

in synchronization with a rising edge of the clock signal, the registers 19 of the processing elements 7a, 7b, and 7c output the input data DI2 to the multipliers 13a, and the registers 22 output the coefficients a02, a12, and a22 to the multipliers 13a. The multipliers 13a of the processing elements 7a, 7b, and 7c multiply the input data DI2 by the coefficients a02, a12, and a22 and output multiplication data to the registers 13b. The registers 13b of the processing elements 7a, 7b, and 7c hold the multiplication data.

The shift reregisters 3 perform in synchronization with a rising edge of the clock signal. Accordingly, the coefficients a00, a10, and a20 are held in the registers 3Rn-2 in the n-2-th stages, the coefficients a02, a12, and a22 are held in the registers 3Rn-1 in the n-1-th stages, and the coefficients a01, a11, and a21 are held in the registers 3Rn in the last stages. At that time, the coefficients a00, a10, and a20 output from the register 3Rn in the last stages are held in the registers 22, respectively. Furthermore, a bit shift process and a bit mask process are performed by the shift/mask circuits 17 on input data DI3 (not illustrated) that is input in synchronization with a rising edge of the clock signal, and the input data DI3 is held in the respective registers 19.

The reconfigurable circuit 1 repeats the above-described performance. After 5 clock cycles from the initial setting state, the processing element 7a outputs output data DOa satisfying expression (4), the processing element 7b outputs output data DOb satisfying expression (5), and the processing element 7c outputs output data DOc satisfying expression (6). The reconfigurable circuit 1 adds the output data DOa, DOb, and DOc from the processing elements 7a, 7b, and 7c by using an adder circuit (not illustrated), so as to calculate the image data Y11 expressed by expression (7) as new image data of the image data x11 of the target pixel in the operation execution unit x11 illustrated in FIG. 17. Also, the reconfigurable circuit 1 can calculate the image data Y satisfying the following expression (8) as new image data of the target pixel at every 3 cycle clocks after five clocks.

Y11=a00×x0(i−1)+a01×x0i+a02×x0(i+1)+a10×x1(i−1)+a11×x1i+a12×x1(i+1)+a20×x2(i−1)+a21×x2i+a22×x2(i+1) (8)

Herein, note that i is an integer satisfying 1≦i≦n-1.

In the reconfigurable circuit 1, read from the line buffers LB0 to LB2 starts before all the image data segments x00 to x22 included in the operation execution unit x11 have been read. Therefore, the reconfigurable circuit 1 can perform a pipeline process.

As described above, according to this example, the reconfigurable circuit includes the processing elements 7a, 7b, and 7c and thus does not include the counter element 137, the data delay element 136, and the RAM elements 121, 122, and 123, unlike the conventional reconfigurable LSI 201. Accordingly, the space for the processing element in the semiconductor chip can be saved. Also, in the reconfigurable circuit 1 according to this example, the chip size can be reduced because the number of processing elements is reduced. Furthermore, in the reconfigurable circuit 1, a network is not occupied by the counter element and so on unlike in the conventional circuit, so that a wiring load reduces and high speed performance can be realized.

Although a few preferred embodiments of the present invention have been shown and described, it would be appreciated by those skilled in the art that changes may be made in these embodiments without departing from the principles and spirit of the invention, the scope of which is defined in the claims and their equivalents.

What is claimed is:

1. A processing element comprising:
a shift register including n stages of registers mutually connected in series, and rotating held data among the n stages of registers in synchronization with a clock signal; and
a number-of-stages determining circuit determining a number of stages to be used among the n stages of registers,
wherein an output terminal of the register in a last stage connects to an input terminal of the register in a first stage.

2. The processing element according to claim 1, wherein the number-of-stages determining circuit includes a plurality of selectors, each of the selectors being placed between adjoining registers among the n stages of registers, each of the selectors receiving the held data output from the register in the anterior stage of the adjoining registers and the held data output from the register in the last stage, and each of the selectors selecting the held data in any of the register in the anterior stage and the register in the last stage and outputting the selected held data to the register in the posterior stage of the adjoining registers.

3. The processing element according to claim 1, wherein the held data includes coefficients of a spatial filter used in image processing.

4. The processing element according to claim 1, further comprising:
an operation unit to perform an operation on the held data output from any one of the n stages of registers in synchronization with the clock signal and input data from the outside.

5. The processing element according to claim 4, wherein the operation unit performs an operation on the held data output from the register in the last stage and the input data.

6. The processing element according to claim 4, wherein the operation unit includes a multiplier circuit to multiply the held data by the input data.

7. The processing element according to claim 6, wherein the operation unit includes an accumulating adder circuit to cumulatively add pieces of data output from the multiplier circuit.

8. The processing element according to claim 1, further comprising:
an operation unit to perform an operation on input data from the outside based on the held data output from any one of the n stages of registers in synchronization with the clock signal.

9. The processing element according to claim 8, wherein the operation unit performs an operation on the input data based on the held data input to the register in the last stage.

10. The processing element according to claim 8, wherein the operation unit includes an accumulating adder circuit in which the number of cumulative additions of the input data is controlled based on the held data.

11. The processing element according to claim 7, wherein output timing of data after operation is controlled based on the held data in the operation unit.

12. The processing element according to claim 4, further comprising:
a shift/mask circuit to perform a bit shift process and a bit mask process on the input data and output the input data to the operation unit.

13. A reconfigurable circuit comprising:
a shift register including n stages of registers mutually connected in series, and rotating held data among the n stages of registers in synchronization with a clock signal; and
a number-of-stages determining circuit to determine a number of stages to be used among the n stages of registers,
wherein an output terminal of the register in a last stage connects to an input terminal of the register in a first stage.

14. A processing method comprising:
providing a shift register including n stages of registers;
connecting the n stages of registers mutually in series;
rotating held data among the n stages of registers in synchronization with a clock signal;
determining a number of stages to be used among the n stages of registers, and connecting an output terminal of a register in the last stage to an input terminal of a register in the first stage.
